(19) United States
(12) Patent Application Publication
(10) Pub. No.: US 2003/0008462 A1
(43) Pub. Date: Jan. 9, 2003

(54) Insulated gate field effect transistor and manufacturing thereof

(75) Inventors: Masatada Horiuchi, Koganei (JP); Takashi Takahama, Higashimurayama (JP); Kazuhiro Ohnishi, Kodaira (JP); Katsuhiro Mitsuda, Koganei (JP)

Correspondence Address: Miles & Stockbridge P.C., Suite 500, 1751 Pinnacle Drive, McLean, VA, 22102-3833, US

(73) Assignee: Hitachi, Ltd.

(21) Appl. No.: 10/164,074

(22) Filed: Jun. 7, 2002

(30) Foreign Application Priority Data
Jun. 12, 2001 (JP) 2001-176478

(51) Int. Cl. H01L 21/8238; H01L 29/76; H01L 21/336; H01L 31/062; H01L 29/94; H01L 31/119; H01L 31/113; H01L 21/76

(52) U.S. Cl. 438/282; 438/289; 438/217; 257/404; 438/404

(57) ABSTRACT

An impurity having a high electrical activation rate is introduced into a channel region, while an In implanted layer is formed in a very shallow region of the channel region. Impurities B, P are re-distributed such that their maximum impurity concentrations are reached at the same depth of a maximum impurity concentration in the In implanted layer, to form channel impurity regions which electrically act as impurities such as B, P, with a similar depth distribution to that of In. The resulting impurity distribution contributes both to the prevention of a punch-through phenomenon and to a large current driving capability of a highly miniaturized complementary MOS transistor.

### BACKGROUND OF THE INVENTION

The present invention relates to a highly miniaturized insulated gate (commonly referred to as “MOS”) field effect transistor which can operate at a low voltage and drive a large current, and a manufacturing method thereof.

The trend toward higher performance of insulated gate field effect transistors (hereinafter referred to as the “MOSFET”) for forming part of a very high density integrated circuit device has been so far accomplished through a reduction in transistor areas, and miniaturization of gate dimensions in order to provide the advantage resulting from a reduction in a supplied power voltage and a parasitic capacitance based on a scaling low. Due to an increase in the concentration of impurities in a substrate based on the scaling law, the concentrations of impurities on the surface and inside of the substrate have been increased to 5×10¹⁷/cm³ to 1×10¹⁸/cm³ just as the base impurity concentration of a bipolar transistor, for operating a MOSFET having a gate length of 100 nm at a power voltage of 1.2 V. Therefore, as long as the scaling law is relied on to advance the miniaturization in the future on the basis of a conventional substrate impurity concentration distribution, there is no solution except for a further increase in the concentrations of impurities on the surface and inside of the substrate. A higher concentration of the impurities within a substrate would give rise to grave shortcoming such as a lower mobility due to an increased coulomb scattering probability, an increased source-drain leakage current (GIDL: gate induced drain leakage) under a zero or negative gate voltage condition at a drain diffusion layer end, an increased hot carrier deterioration, and the like, or a lower reliability, thereby resulting in suppression to higher performance of MOSFET.

The foregoing factors of suppressing the higher performance of MOSFET result from a higher impurity concentration on the surface of a semiconductor substrate in which a channel is formed. From a view point of pursuing higher performance of miniaturized MOSFET, a configuration for providing a depth profile impurity concentration distribution, as shown in FIG. 2, has been proposed for reducing only the concentration of impurities on the surface, as commonly referred to as a super-retrograde well structure. FIG. 2 shows a depth profile impurity concentration distribution from the surface of a semiconductor substrate within a channel region beneath a gate electrode in an N-channel MOS transistor (hereinafter abbreviated as “NMOS transistor”). Due to a small mass of boron (B), conventionally used in wide applications, only boron implanted by ion implantation could merely realize a gently-sloping depth profile distribution. For realizing a low concentration in a surface region and an abrupt P-conductive type impurity concentration distribution, indium (In) having a large mass is implanted by ion implantation. Boron (B) is additionally implanted for preventing bulk punch-through current flow such that the concentration is higher in a deeper region. The super-retrograde well structure is built by summing up respective impurity distributions for B and In, each having a maximum impurity concentration of 1×10¹⁸/cm³ or higher.

Another known approach for pursuing the higher performance of miniaturized MOSFET is a pocket structure, as commonly called in the art. As illustrated in FIG. 3, the pocket structure comprises a P-conductive type impurity region 5 formed by implanting B using a gate electrode 4 as an implantation blocking mask; and a shallow N-conductive type source diffusion layer 6 and a drain diffusion layer 7 formed within the P-conductive type impurity region 5, similarly using the gate electrode 4 as an implantation blocking mask. The pocket structure solves the extinction of a built-in potential in a source region due to a drain electric field by locally increasing the substrate impurity concentration to prevent the punch-through current flow. It is known that, even in the pocket structure, impurities introduced from a gate edge sum up in a central portion of the channel to increase the impurity concentration therein due to a gate electrode length shortening, causing so-called reverse short channel effects.

Though not directly related to the channel impurity distribution structure, a peculiar property of In is known to change the distribution of an impurity P within Si. A technique for controlling the depth of a deep source/drain junction, taking advantage of this property, is known from JP-A-11-87706.

In the super-retrograde well structure, In is used in an NMOS transistor, while As (arsenic) or Sb (antimony) is used in a PMOS transistor. These are all heavy elements which inevitably cause crystal defects when they are implanted in large dose by ion implantation. Particularly, with In, crystal defects are recognized when a maximum implanted concentration reaches 2×10¹⁸/cm³ or higher. In, though it acts as an acceptor within Si, has an energy level positioned at approximately 0.16 eV from a valence band edge, so that it is activated as an acceptor merely on the order of 10 percent at a room temperature even at a dose of 1×10¹⁸/cm³. The activation is achieved when the energy band is bent by an applied electric field. However, In exhibits a characteristic that a threshold voltage depends on the channel length, referred to as a so-called short channel effect, even in a relatively long channel length region ranging approximately from 0.5 μm to 5 μm in which the threshold voltage hardly depends on the channel length. The foregoing dependency of the activation rate on the electric field is hard to handle, as compared with conventionally widely used B and the like. Additionally, In has another hard-to-handle characteristic that a segregation limit within an Si substrate is as low as approximately 10¹⁸/cm³, leading to a limited upper limit for an acceptor concentration to restrict freedom in process designing.

### SUMMARY OF THE INVENTION

It is an object of the present invention to provide a higher performance miniaturized MOSFET which completely obviates or shuts off a source-drain punch-through current path and drives a larger current. More particularly, it is an object of the present invention to completely solve crystal defects growth and junction leakage current problems associated with the introduction of In, which has been a challenge for realizing an ideal super-retrograde well, and a problem inherent to In which exhibits a low activation rate as an acceptor, and the dependency of the threshold voltage on the channel length even up to a long channel region, to realize a high concentration impurity region which has an abrupt impurity concentration slop, continuous to a low concentration on the surface of the channel. Consequently, the present invention aims at realizing a high performance miniaturized MOSFET which can completely prevent the surface punch-through phenomena and drive a larger current.

It is another object of the present invention to solve problems inherent to In, i.e., a low segregation limit concentration and the inability to provide a sufficient acceptor concentration, and to realize a super-retrograde well which has a sufficiently high acceptor concentration and provide a high degree of freedom in designing.

It is a further object of the present invention to completely solve problems associated with the higher performance of a miniaturized PMOS transistor formed within an N-type substrate region, with introduction of As or Sb in large quantities for realizing an ideal super-retrograde well, i.e., the occurrence of crystal defects and an increased junction leakage current.

It is a further object of the present invention to provide a miniaturized complementary MOS transistor (hereinafter referred to as the “CMOS transistor”) which has an N-type region and a P-type region in the same semiconductor substrate, and an NMOS and a PMOS transistor in the respective regions, wherein the miniaturized CMOS transistor is configured to drive a larger current and operate at a higher speed by setting a channel impurity concentration distribution in each of the NMOS and PMOS transistors to have the same depth profile distribution, and simultaneously providing the NMOS and PMOS transistors with the capabilities to drive a larger current. While the higher performance of the CMOS transistor is realized by comprising the channel impurity distributions of the NMOS and PMOS transistors in the super-retrograde well structure, it is another object of the present invention to do so without increasing the number of fabrication process steps for the realization of higher performance CMOS transistor, and accordingly at a low cost.

From a view point of pursuing an even larger current drivability in the MOSFET characteristics, the present invention provides a MOSFET having gate insulating film in a reduced thickness and a reduced gate length based on a scaling law. To this end, the present invention employs a structure to determine an effective channel region. A gate patterning process of up-to-date miniaturization techniques and source and drain diffusion layers formation by using the gate electrode as an ion implantation mask are applied. The present invention also employs an ion implantation condition for the diffusion layers to meet requirements of a highly concentrated ultra shallow junction for sufficiently suppressing a punch-through phenomenon between the source and drain and for reducing a source resistance as low as possible. Annealing sequences are minimized for activation in order to reduce subsequent junction depth spread.

A basic concept of the present invention relies on a phenomenon, which was found in course of an investigation on diffusion of P-conductive type In introduced into an Si single crystal substrate by ion implantation, that impurity diffusion layers, into which impurities such as B, P, As had been previously introduced, largely varied due to the introduction of In even in a low concentration. Specifically, a sample was made by doping boron by ion implantation from the surface of an Si single crystal substrate having a crystal plane orientation (100) and formed with a surface passivation oxide film of 2.5 nm thick under the conditions of an acceleration energy at 20 keV and a dose of 3×10¹³/cm². In was additionally doped into the sample by ion implantation under the conditions of an acceleration energy at 20 keV and a dose of 5×10¹¹/cm². The sample was then annealed at a high temperature for a short time, specifically, at 1000° C. for 10 seconds for activating the implanted ions. Secondary ion mass spectroscopy was used to measure depth profile impurity distributions of B and In for each sample before and after the thermal activation. The result of the measurement showed that before the thermal activation, a maximum impurity concentration of B was 4×10¹⁸/cm³ which was reached at a depth of approximately 100 nm from the surface of the Si substrate, while a maximum impurity concentration of In was 2×10¹⁸/cm³ which was reached at a depth of approximately 15 nm from the surface of the Si substrate. On the other hand, the impurities B and In after the thermal activation presented quite peculiar distributions. Specifically, a depth profile distribution of B showed a maximum impurity concentration depth moved to approximately 18 nm from the surface of the Si substrate, the maximum concentration increased to 5×10¹⁸/cm³, and a more abrupt distribution than before the thermal activation. The concentration of B at the surface of the Si substrate was observed to be reduced, rather than increased from the value 1×10¹⁷/cm³ before the thermal activation. On the other hand, in a sample implanted only with B without simultaneous implantation of In, a maximum impurity concentration was reached at a depth of approximately 100 nm from the surface of the Si substrate, and reduced to 2×10¹⁸/cm³. Also, the impurity distribution was spread, and the concentration at the surface was increased to approximately 1×10¹⁸/cm³. The result of the foregoing experiment shows that the additional implantation of In causes the impurity distribution of B after the thermal activation to be more abrupt than the distribution immediately after B was implanted. This result can be justified on the assumption that In atoms attract other impurity atoms i.e., effecting a pinning phenomena.

For examining the pinning effect of In for other impurity atoms, an investigation was made on the influence of In implantation on the depth profile distributions of P and As. The depth profile distributions of P and As doped by ion implantation were measured by the secondary ion mass spectroscopy before and after the thermal activation. The result of the measurements showed that low concentration distribution regions of both P and As were moved toward the depth at which the maximum In concentration was reached, and the impurity concentration at the surface of the Si substrate was further reduced from immediately after the ion implantation.

The present invention utilizes the newly found phenomenon for improving an impurity distribution in a channel region of a miniaturized MOSFET. With an NMOS transistor having a gate length of 100 nm taken as an example, after B was doped by ion implantation to provide an impurity concentration distribution in the channel region which presented a maximum impurity concentration on the order of 2×10¹⁸/cm³ at a depth of approximately 50 nm from the surface of the substrate, In was additionally doped by ion implantation such that a maximum impurity concentration on the order of 1×10¹⁸/cm³ was reached at a depth of approximately 15 nm from the surface of the substrate. Then, the resulting NMOS structure was annealed at a high temperature for a short time for activation of the introduced impurities and re-distribution of the impurities. As a result of the re-distribution, the depth at which the doped B reached the maximum impurity concentration was moved to a depth of 20 nm or less from the surface of the substrate, the maximum impurity concentration was reduced to approximately 3×10¹⁸/cm³, and the impurity concentration on the surface of the substrate was also reduced to approximately 1×10¹⁷/cm³, resulting in the formation of a super-retrograde well. The anneal may be followed by subsequent steps from the formation of a gate insulating film and a gate electrode. With a PMOS transistor having a gate length of 100 nm, As was doped by ion implantation at acceleration energy of 20 keV such that a maximum impurity concentration on the order of 3.5×10¹⁸/cm³ was reached at a depth of approximately 15 nm from the surface of the substrate. Subsequently, In was additionally doped by ion implantation such that a maximum impurity concentration on the order of 1×10¹⁸/cm³ was reached at a depth of approximately 15 nm from the surface of the substrate. Subsequently, the resulting PMOS structure was annealed at a high temperature for a short time for activation of the introduced impurities and re-distribution of the impurities. While the short-time, high-temperature anneal did not cause a change in the depth at which the doped As reached the maximum impurity concentration, the maximum impurity concentration was increased to approximately 4×10¹⁸/cm³, whereas the impurity concentration at the surface of the substrate was reduced to approximately 1×10¹⁷/cm³. The anneal may be followed by subsequent steps from formation of a gate insulating film and a gate electrode, as is the case with the NMOS transistor. In this event, In, which has a conductive type reverse to that of As, compensates for an N-conductive type carrier concentration and acts to increase a sheet resistance. However, a region into which In was introduced is a region for cutting off a punch-through current path, different from the channel region for controlling an operating current, so that the introduced In will never adversely affect an improvement on the performance of a miniaturized MOSFET. It should be noted that similar result was shown when B and In, and As and In were doped by ion implantation in the reverse order in the foregoing ion implantation. Alternatively, P may be doped by ion implantation instead of the ion implantation of As.

The performance of CMOS transistor can be readily improved by integrating the NMOS and PMOS fabrication process steps. Specifically, In may be doped by ion implantation at acceleration energy of 20 keV over the entire surface of a P-conductive type substrate region in which an NMOS transistor is to be formed, and over the entire surface of an N-conductive type substrate region in which a PMOS transistor is to be formed such that a maximum impurity concentration on the order of 1×10¹⁸/cm³ is reached at a depth of approximately 15 nm from the surface of the substrate. Subsequently, B may be selectively doped into the P-conductive type substrate region by ion implantation such that a maximum impurity concentration set on the order of 2×10¹⁸/cm³ is reached at a depth of approximately 50 nm from the surface of the substrate, while As may be selectively doped into the N-conductive type substrate region by ion implantation at acceleration energy of 20 keV such that a maximum impurity on the order of 3.5×10¹⁸/cm³ is reached at a depth of approximately 15 nm from the surface of the substrate. Then, the resulting CMOS structure is annealed at a high temperature for a short time for activation of B, As and re-distribution of the impurities. In this way, the depth profile impurity concentration distribution in a channel region of each of the NMOS and PMOS transistors, forming part of CMOS, can be created in a super-retrograde well structure with the same distribution, irrespective of the difference in the impurity concentration distribution between B and As.

According to the foregoing approach, it is possible to realize the super-retrograde well structure having an impurity concentration distribution which presents a sufficiently low concentration at the surface of the channel region and abruptly increases from the low concentration at the surface only by implanting the impurity B or As without relying on the introduction of In in a high concentration. Thus, the present invention can eliminate crystal defects caused by the introduction of In in a high concentration, which has been a problem in the prior art approach, and prevent an increase in junction leakage current. Further according to the foregoing approach, since the impurity which electrically constitutes the super-retrograde well structure is B or As or P, it is possible to solve the problem of a low activation rate and low segregation limit concentration, caused by a deep energy level of In, i.e., the problem of the dependency of a threshold voltage on the channel length, which can extend to a long channel region, and the problem of a low acceptor concentration. Since a surface punch-through stopper diffusion layer, identical to In in the abruptness of the ion implantation impurity distribution, can be implemented by light atoms such as B, As, P and the like which have high activation rates and are less susceptible to crystal defects formation, it is possible to suppress a short channel effect due to the punch-through phenomenon while realizing high mobility properties based on a low channel impurity concentration structure at the surface. In addition, a miniaturized MOSFET having a small leakage current and a large current characteristic can be implemented in each of NMOS, PMOS and CMOS structures.

As another approach, it is estimated that Al (aluminum), Ga (gallium) and the like can produce an interaction with B. In this event, these elements present a number of disadvantages as compared with In, for example, Al and Ga have smaller mass than In; it is difficult in principle to set an abrupt profile of Al or Ga at an arbitrary depth through ion implantation; Al and Ga have a diffusion speed too high in a Si substrate to control in a general semiconductor device manufacturing process; and their activation rates as acceptor impurities are too low to be practical, in considering applications in a miniaturized MOSFET; and the like. However, Ga, for example, has excellent properties such as a high segregation limit concentration of 2×10¹⁹/cm³ within Si; an acceptor level which is 0.072 eV from the valence band edge, one half or less of that of In; readiness of activation; and the like. Therefore, Al or Ga is preferably used together with In.

Other objects, features and advantages of the invention will become apparent from the following description of the embodiments of the invention taken in conjunction with the accompanying drawings.

### BRIEF DESCRIPTION OF THE DRAWINGS

FIG. 1 is a cross-sectional view of a completed insulated gate field effect transistor according to a first embodiment of the present invention.

FIG. 2 is a graph showing an impurity depth profile distribution from the surface of a semiconductor substrate in a channel region of a conventional insulated gate field effect transistor.

FIG. 3 is a cross-sectional view illustrating a conventional insulated gate field effect transistor when it is completed.

FIG. 4 is a graph showing an impurity depth profile distribution from the surface of a semiconductor substrate in a channel region of the insulated gate field effect transistor according to the present invention.

FIGS. 5 and 6 are cross-sectional views illustrating an order of steps for fabricating the insulated gate field effect transistor according to the first embodiment of the present invention.

FIGS. 7 to 9 are cross-sectional views illustrating an order of steps for fabricating an insulated gate field effect transistor according to a second embodiment of the present invention.

FIG. 10 is a cross-sectional view of a completed insulated gate field effect transistor according to a second embodiment of the present invention.

FIG. 11 is a cross-sectional view of a completed insulated gate field effect transistor according to a third embodiment of the present invention.

FIG. 12 is a cross-sectional view of a completed insulated gate field effect transistor according to a fourth embodiment of the present invention.

### DESCRIPTION OF THE EMBODIMENTS

In the following, the present invention will be described in detail in connection with several embodiments thereof. For ease of understanding, the following description will be made with reference to the accompanying drawings in which main portions are illustrated in enlarged views, as compared with other portions. It should be understood that the material, conductive type, manufacturing conditions and the like of respective regions are not limited to the description of the embodiments but may be modified in various manner.

<First Embodiment>

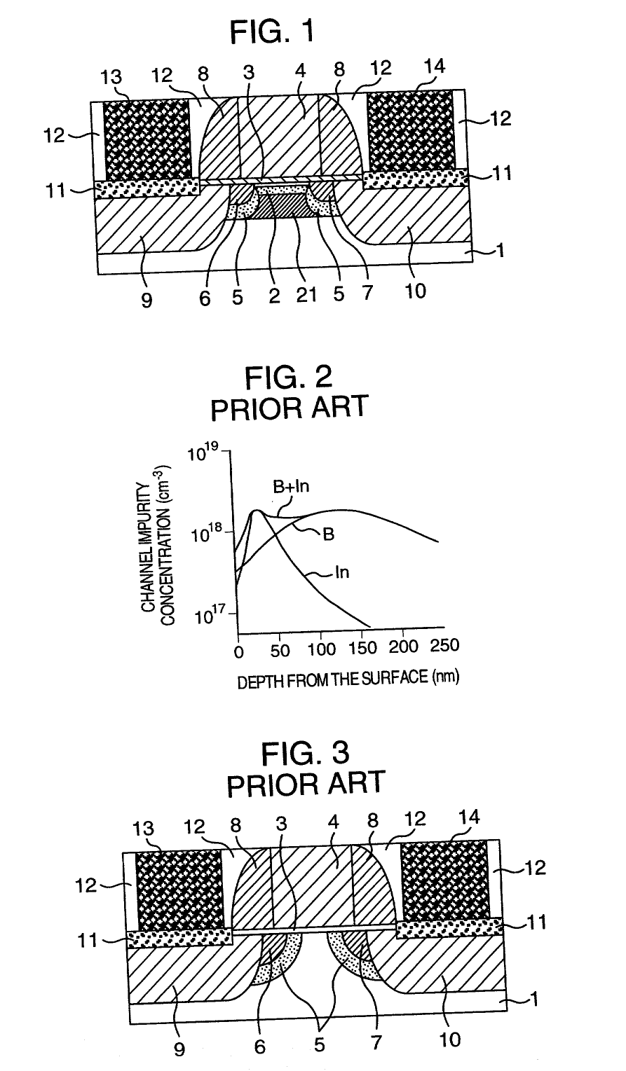

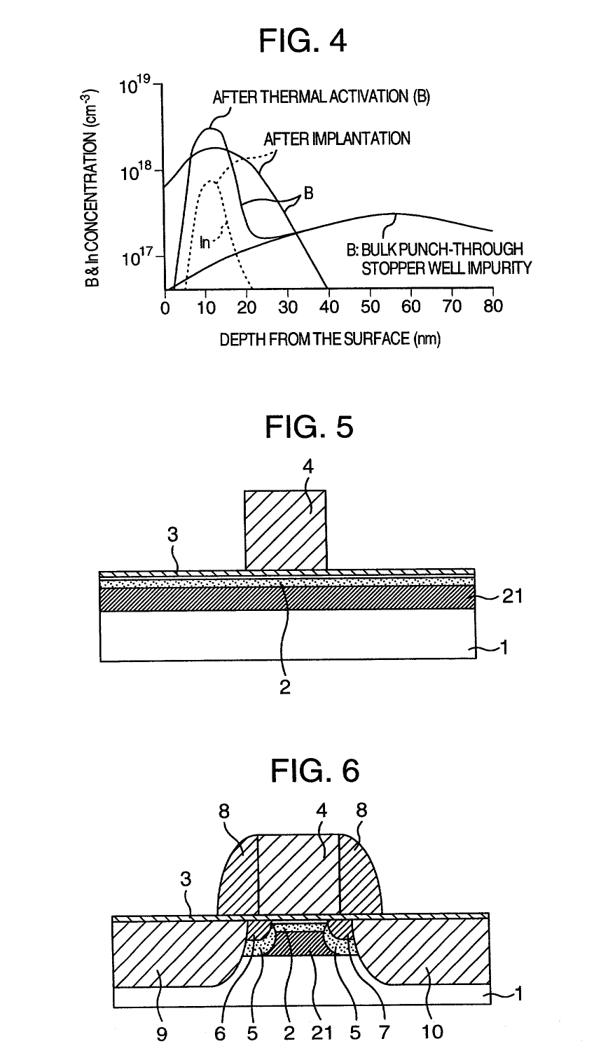

FIG. 1 is a cross-sectional view illustrating a completed MOSFET according to a first embodiment of the present invention; FIGS. 5 and 6 are cross-sectional views illustrating an order of steps for fabricate the MOSFET; and FIG. 4 is a graph showing an impurity depth profile distribution from the surface of a semiconductor substrate in a channel region of the MOSFET.

A device isolation insulator region (not shown) for defining an active region was formed in a semiconductor substrate 1 formed of a P-conductive type single crystal Si substrate having a plane orientation (100) and a diameter of 20 cm. Then, a P-conductive type well was formed by ion implantation for adjusting an impurity concentration in the substrate, and the resulting semiconductor substrate 1 underwent a diffusion anneal by a known technique. Subsequently, a silicon oxide film formed on the surface of the semiconductor substrate 1 was selectively removed therefrom, and a silicon oxide film (not shown) of 2 nm thick was deposited again on the semiconductor substrate 1. The silicon oxide film was used as a surface passivation film in an ion implantation step. Then, B implanted layer 21 was formed by doping B into the semiconductor substrate 1 by ion implantation under the conditions of acceleration energy of 20 keV and a dose of 3×10¹³/cm². Subsequently, an In implanted layer 2 was formed by doping In by ion implantation at acceleration energy of 20 keV to reach a maximum impurity concentration of approximately 1×10¹⁸/cm³. The ion implantation was performed with a tilt angle of 7 degrees or more from the perpendicular with respect to the semiconductor substrate 1 having the plane orientation (100) in order to prevent a so-called channeling phenomenon, i.e., an unexpectedly extended projection range depending on a particular single crystal plane. It should be noted that perpendicular ion implantation of In, without tilt angle, under the foregoing condition could result in an impurity concentration distribution which would have a tail extending to a depth of approximately 1 μm. The implantation tilt angle may be increased, for example, to approximately 45 degrees, if desired, based on the performance of an ion implanter without causing any problem. It should be understood that in this event, ions are implanted to a different depth depending on a particular tilt angle at which ions are implanted.

After the foregoing consecutive ion implantation, the resulting semiconductor substrate 1 was annealed at a high-temperature for a short time, specifically, at 950° C. for 10 seconds. A temperature rise rate was set to 100° C./second. After the anneal, a B depth profile distribution was measured for a separately prepared sample, which had undergone similar processing, by secondary ion mass spectrography. The result of the measurement showed that a maximum impurity concentration depth was moved to approximately 18 nm from the surface of the substrate, a maximum concentration was also increased to 5×10¹⁸/cm³, and the measured B distribution was changed to be more abrupt than that before the anneal. The surface concentration of B was observed to have a tendency to a reduction, rather than an increase from the value 1×10¹⁷/cm³ before the anneal. An impurity re-distribution characteristic in a similar anneal to a sample doped only with B by ion implantation, without additional implantation of In, exhibited a maximum impurity concentration depth at approximately 100 nm from the surface, a maximum impurity concentration reduced to 2×10¹⁸/cm³, a spread distribution, and a surface concentration increased to approximately 1×10¹⁸/cm³. The foregoing result shows that the additional implantation of In provides a more abrupt B impurity distribution after the anneal, even compared with the distribution immediately after the implantation of B. The foregoing result can be justified on the assumption that In atoms pin other impurity atoms. After the short-time anneal, a thermal oxide film was formed in a thickness of 1.8 nm, and the surface of the oxide film was nitrized by an NO gas to stack an nitride film of 0.2 nm thick which served as a gate insulating film 3. Subsequently, an amorphous Si film heavily doped with P was deposited on the gate insulating film 3 in a thickness of 250 nm by a chemical vapor deposition method, and patterned into a gate electrode 4 of 100 nm thick using electron beam lithography. A reduction in resistance of the gate electrode 4 may be implemented by selectively doping a desired gate electrode region with P or B by ion implantation in a high concentration based on a conventionally known complementary MOS fabricating method, instead of adding the impurities as described above, without causing any problem (see FIG. 5).

In the state illustrated in FIG. 5, As ions were implanted perpendicularly at acceleration energy of 5 keV and a dose of 1×10¹⁵/cm² to form a shallow source diffusion layer 6 and a shallow drain diffusion layer 7. Subsequently, B were doped by ion implantation to surround the shallow source diffusion layer 6 and shallow drain layer 7 to form an N-conductive type punch-through stopper diffusion layer 5 for preventing the punch-through.

Next, a silicon oxide film of 50 nm thick was deposited over the entire surface at a low temperature of 400° C. by a plasma aided deposition method, and was etched by anisotropic dry etching to selectively leave the silicon oxide film only on a side wall of the gate electrode 4 to form a gate side wall insulator film 8. Then, an N-type high concentration drain diffusion layer 10 and an N-type high concentration source diffusion layer 9 were formed using the gate side wall insulator film 8 as an ion implantation blocking mask. The ion implantation was performed using As ions under the conditions of an acceleration energy at 40 keV and a dose of 4×10¹⁵/cm² (see FIG. 6).

In the state illustrated in FIG. 6, after the implanted ions were annealed for activation at 950° C. for 10 seconds, a Co film was deposited in a small thickness over the entire surface by a sputtering method and annealed at 500° C. for a short time for silicidation. An unreacted Co film was removed by a mixture of hydrochloric acid and hydrogen peroxide to selectively leave a Co silicide film 11 on an exposed portion of the Si substrate 1. In this state, the Co silicide film 11 was reduced in resistance by a short-time anneal at 800° C. Next, after a thick silicon oxide deposited film was formed over the entire surface, the surface was planarized by mechanical chemical polishing to form a surface passivation insulator film 12. After the surface passivation insulator film was formed with openings at desired regions, an TiN film serving as a metallization diffusion barrier material, and a W film serving as metallization were deposited and polished for planarization to selectively leave the W film only in the openings. Subsequently, a metal film mainly composed of aluminum was deposited in accordance with a desired circuit configuration, and patterned to form metallization including a drain electrode 14 and a source electrode 13, thus completing the fabricating of a MOSFET (see FIG. 1).

The MOSFET according to this embodiment, fabricated through the foregoing fabricating steps, was compared with a MOSFET in a conventional structure under the conditions that the gate length was 100 nm. In the conventional MOSFET which only used B for a punch-through stopper diffusion layer in a channel region, had a small depth profile impurity concentration gradient in the channel region, and has a surface impurity concentration as high as approximately 1×10¹⁸/cm³, a source-drain current value at a gate voltage of 0 V was 8.8×10⁻⁹ A per 1 μm of gate width, and the source-drain current value at the gate voltage of 1.2 V was 0.76 mA per 1 μm of gate width. On the other hand, in the MOSFET according to this embodiment which had a channel surface impurity concentration as low as approximately 1×10¹⁷/cm³, and a channel impurity distribution that exhibited an increase of impurity concentration at an abrupt gradient from the channel surface in the depth direction, a source-drain current value at a gate voltage of 0 V was 7.8×10⁻⁹ A per 1 μm of gate width. In spite of a small leakage current, the source-drain current value at the gate voltage of 1.2 V was 0.89 mA per 1 μm of gate width. Thus, an increase of current by 17 percent was accomplished in the MOSFET of the foregoing embodiment. In an MOSFET which was fabricated to meet the condition of the maximum channel impurity concentration of 5×10¹⁸/cm³, identical to the MOSFET of the embodiment, for preventing the surface punch-through only by doping In by ion implantation, a leakage current at a gate voltage of 0 V was extremely large, specifically, 1 μA or more per 1 μm of gate width. This is because the implantation of In ions in large doses caused crystal defects.

A Vth value of the miniaturized MOSFET according to this embodiment was 0 V at a drain voltage of 1.2 V. In addition, in regard to the dependency of Ids on Vg of the miniaturized MOSFET according to this embodiment, a difference in threshold voltage was merely as small as 0.12 V when the drain applied voltage was 1.2 V and 0.1 V, thus making it apparent that the miniature MOSFET of this embodiment excelled in the drain induced barrier lowering (DIBL) characteristic. From this fact, it is clarified that the impurity concentration depth distribution in the channel region beneath the gate electrode of the miniaturized MOSFET according to this embodiment is sufficiently abrupt in the depth direction of the substrate, so that the surface punch-through phenomenon is sufficiently suppressed. While the foregoing embodiment has been described for an NMOS structure, the present invention may be applied to a PMOS structure in which the conductive types are reverse, and a CMOS structure which is a composite of NMOS and PMOS, without causing any problem.

In the foregoing embodiment, MOSFETs were fabricated on a trial basis under a variety of conditions using a dose of In as a parameter, and it is revealed that crystal defects are caused by heavy ion implantation at a dose of 5×10¹⁹/cm³ or more. Since the occurrence of crystal defects is not preferable, the dose should be limited to 1×10¹⁹/cm³ or less. In regard to a lower limit for the dose, 5×10¹⁷/cm³ is desired since the effect of the foregoing embodiment is observed with the dose of 5×10¹⁷/cm³ or more.

<Second Embodiment>

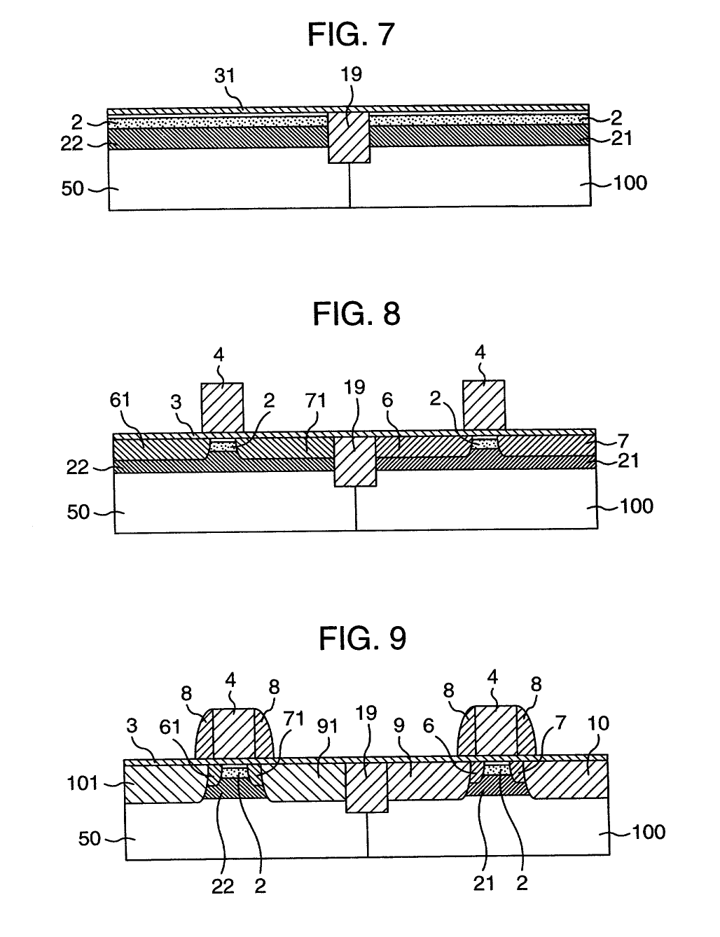

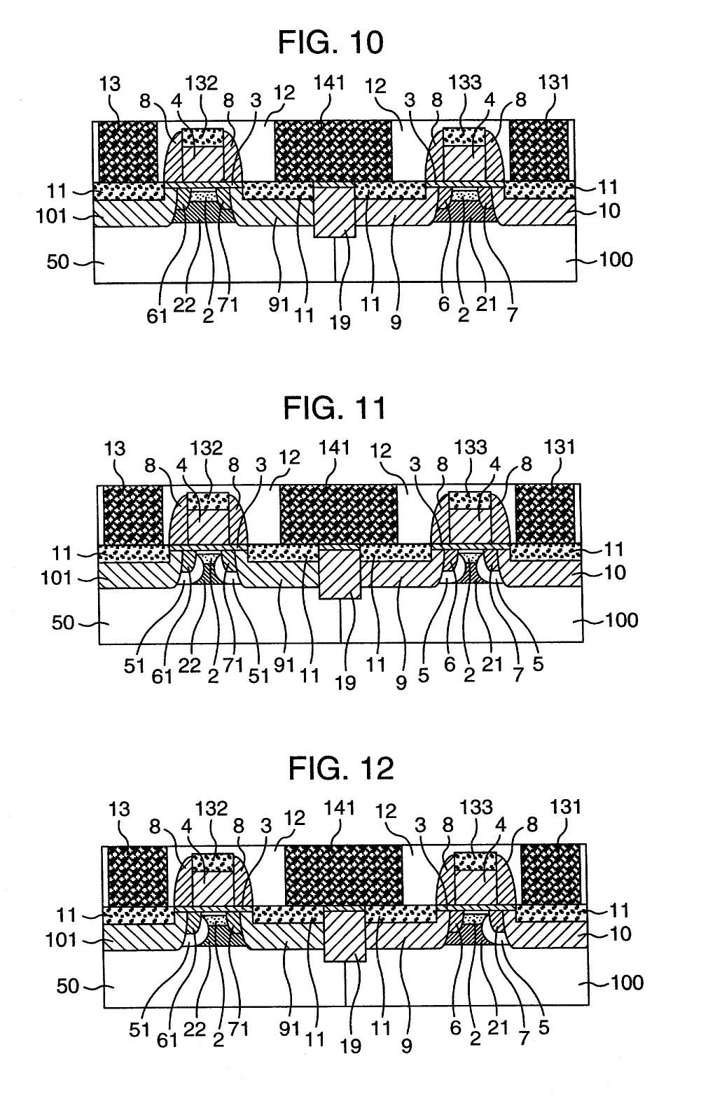

FIG. 10 is a cross-sectional view illustrating a completed MOSFET according to a second embodiment of the present invention, and FIGS. 7 to 9 are cross-sectional views illustrating an order of process steps for fabricating the MOSFET.

A device isolation insulator region 19 for defining an active region was formed in a semiconductor substrate formed of a P-conductive type single crystal Si substrate having a plane orientation (100) and a diameter of 20 cm. Then, an N-conductive type well region 50 and a P-conductive type well region 100 were formed by a known technique by doping P and B into predetermined regions of the Si substrate 1 by ion implantation, and annealing the implanted P and B for diffusion and activation. From this state, P was selectively doped into the N-conductive type well region 50 by ion implantation under the conditions of an acceleration energy at 30 keV and a dose of 2×10¹³/cm², while B was selectively doped into the P-conductive type well region 100 by ion implantation under the conditions of an acceleration energy at 20 keV and a dose of 2×10¹³/cm² to form an N-conductive type high concentration well layer 22 and a P-conductive type high concentration well layer 21. Subsequently, in this state, In was doped over the entire surfaces of the P-conductive type well region 100 and N-conductive type well region 50 by ion implantation under the conditions of an acceleration energy at an acceleration energy at 10 keV and a dose of 2×10¹²/cm² to form an impurity pinning layer 2. The foregoing In ion implanting conditions define a maximum In impurity concentration of 2×10¹⁸/cm³ at a depth of approximately 12 nm from the surface of the semiconductor substrate. The In concentration at a main surface of the semiconductor substrate was 1×10¹⁶/cm³ (see FIG. 7).

In the state illustrated in FIG. 7, a short-time high-temperature anneal was performed under the conditions of 1000° C. for one second. A depth profile impurity distribution was evaluated for another semiconductor substrate, which had undergone the same processing as the foregoing fabricating steps, by secondary ion mass spectrography. The result of the evaluation showed that no change was substantially found in the In depth profile distribution, a maximum P impurity concentration in the N-conductive type high concentration well layer 22 was 5×10¹⁸/cm³ which was substantially identical to that before the anneal, and the position of the maximum P impurity concentration moved from a depth of 35 nm before the anneal to 12 nm which is substantially the same depth as the maximum In concentration. The P concentration at the surface of the semiconductor substrate was reduced by a factor of three, i.e., to 1×10¹⁷/cm³ or less, showing a change to a more abrupt distribution than the depth profile concentration distribution immediately after the implantation. The foregoing anneal caused the depth at which the maximum B impurity concentration was reached in the P-conductive type high concentration well layer 21 to move from a depth of approximately 60 nm from the surface of the semiconductor substrate to a depth of 12 nm. Also, the B concentration at the surface of the semiconductor substrate was reduced to ⅔, i.e., to 1×10¹⁷/cm³ or less, showing a similar change to a more abrupt distribution than the depth profile concentration distribution immediately after the implantation.

After the anneal, a thermal oxide film of 1.8 nm thick was formed, and its surface was nitrized by an NO gas to stack a nitride film of 0.2 nm thick which served as a gate insulating film 3. Subsequently, an amorphous Si film 4 was deposited on the gate insulating film 3 in a thickness of 150 nm by a chemical vapor deposition. Then, B was selectively doped by ion implantation into the amorphous Si film 4 on the N-conductive type high concentration well layer 22 in a high concentration, while P was selectively doped by ion implantation into the amorphous Si film 4 on the P-conductive type high concentration well layer 21 in a high concentration. Then, the implanted ions were activated by a short-time, high temperature anneal to make a P-conductive type and an N-conductive type Si films. The resulting Si film 4 was patterned into a gate electrode 4 having a minimum dimension of 70 nm by the electron beam lithography. In this state, As was selectively doped into the P-conductive type high concentration well region 21 by ion implantation, using the gate electrode 4 as an implantation blocking mask to form high concentration shallow junction N-conductive type diffusion layers 6, 7. On the other hand, BF₂ was selectively doped into the N-conductive type high concentration well region 22 by ion implantation, likewise using the gate electrode 4 as an implantation blocking mask to from high concentration shallow junction P-conductive type diffusion layers 61, 71. The ion implantation was performed for either case under the conditions of an acceleration energy at 3 keV and a dose of 1×10¹⁵/cm² (see FIG. 8).

In the state illustrated in FIG. 8, a silicon nitride film of 60 nm thick was deposited over the entire main surface, and anisotropically etched to selectively leave the silicon nitride film only on a side wall of the gate electrode 4, as a gate side wall insulating film 8. Subsequently, by ion implantation using the gate side wall insulating film 8 as an implantation blocking mask, As-based N-conductive type deep high concentration source and drain diffusion layers 10, 9 were selectively formed such that they partially overlapped high concentration shallow junction N-conductive type diffusion layers 6, 7. In addition, BF₂-based P-conductive type deep high concentration source and drain diffusion layers 101, 91 were selectively formed such that they partially overlapped the high concentration shallow junction P-conductive type diffusion layers 61, 71. The As was doped by ion implantation under the conditions of an acceleration energy at 40 keV and a dose of 4×10¹⁵/cm², while BF₂ was doped by ion implantation under the conditions of an acceleration energy at 25 keV and a dose of 3×10¹⁵/cm². After the ion implantation, the implanted ions were annealed for activation at 1000° C. for two seconds. After the anneal, the source and drain diffusion layers 10, 9 had a junction depth of approximately 1500 nm (see FIG. 9).

In the state illustrated in FIG. 9, after selectively removing the insulating film remaining on the source and drain diffusion layers 10, 9, 101, 91, a Co film was deposited in a small thickness over the entire surface by sputtering, and annealed at 500° C. for a short time for silicidation. An unreacted Co film was removed by a mixture of hydrochloric acid and hydrogen peroxide to selectively leave a Co silicide film 11 on an exposed portion of the Si substrate 1. In this state, the Co silicide film 11 was reduced in resistance by a short-time anneal at 800° C. Next, after a thick silicon oxide deposited film was formed over the entire surface, the surface was planarized by chemical mechanical polishing to form a surface passivation insulator film 12. After the surface passivation insulator film was formed with openings at desired regions, an TiN film serving as a metallization diffusion barrier material, and a W film serving as metallization were deposited and polished for planarization to selectively leave the W film only in the opening. Subsequently, a metal film mainly composed of aluminum was deposited in accordance with a desired circuit configuration, and patterned to form metallization including an earth potential line 131, a signal output line 141, and a power supply line, thus completing the fabricating of a MOSFET (see FIG. 10).

The MOSFET according to the second embodiment, fabricated through the foregoing fabricating process steps, was compared with a MOSFET in a conventional structure under the conditions that they had the same gate length. The MOSFET according to the second embodiment presents an extremely low impurity concentration of 10¹⁷/cm³ or less at the channel surface both in the P-conductive type well 21 in the NMOS transistor and in the N-conductive type well 22 in the PMOS transistor, and has an abrupt impurity distribution which exhibits a maximum impurity concentration equal to 5×10¹⁸/cm³ at a depth of 12 nm from the surface of the semiconductor substrate. The abrupt impurity distribution is caused by B in the P-conductive type well 21, and by P in the N-conductive type well 22, thus implementing a distribution which cannot be realized by a depth profile distribution provided by the conventional single ion implantation of B or P. While In also exists in the distribution of B or P, In is small in absolute quantity as compared with the impurities B or P, so that its electric role can be ignored. The ion implantation of In does not either cause crystal defects because the dose is small. Specifically, under the condition that the gate length was 70 nm, in a conventional NMOS transistor which used only B as a punch-through stopper diffusion layer in the channel region, had a small depth profile impurity concentration gradient in the channel region, and had a high surface impurity concentration on the order of 2×10¹⁸/cm³, a source-drain current value at a gate voltage of 0 V was 1×10⁻⁸ A per 1 μm of gate width, and the source-drain current value at the gate voltage of 1.2 V was 0.92 mA per 1 μm of gate width. On the other hand, in the MOSFET according to the second embodiment which had a channel surface impurity concentration as low as approximately 1×10¹⁷/cm³, and a channel impurity distribution that exhibited an increase of impurity concentration at an abrupt gradient from the channel surface in the depth direction, a source-drain current value at a gate voltage of 0 V was 8.8×10⁻⁹ A per 1 μm of gate width. In spite of a small leakage current, the source-drain current value at the gate voltage of 1.2 V was 1.18 mA per 1 μm of gate width, thus achieving an increase of current by 22 percent. Further, in regard to the dependency of Ids on Vg of the miniaturized MOSFET according to the second embodiment, a difference in threshold voltage was merely as small as 0.13 V when a voltage applied to the drain was 1.2 V and 0.1 V, thus making it apparent that the miniaturized MOSFET of the second embodiment excelled in the DIBL characteristic. Also, in the PMOS transistor according to the second embodiment, having a gate length of 70 nm, a source-drain current value at the gate voltage of 0 V was 1×10⁻⁸ A per 1 μm of the gate length, and a source-drain current value at the gate voltage of 1.2 V was 0.55 mA per 1 μm of the gate length, thus achieving an increase in current by 20% from a source-drain current value in a conventional PMOS transistor which only used P as a punch-through stopper diffusion layer in a channel region, and had a small depth profile impurity concentration gradient in the channel region. In other words, according to the second embodiment of the present invention, an increase in current was accomplished without the surface punch-through phenomenon both in the NMOS and PMOS transistors. The abrupt channel impurity distribution of the MOSFET according to the second embodiment is achieved by adding the In ion implantation throughout the fabricating of NMOS and PMOS transistors, and by merely adding one step in the fabricating of a CMOS transistor. In this way, a high concentration and small gradient channel impurity distribution provided by only B or P based on the conventional manufacturing method can be modified to a channel impurity distribution which presents a low concentration at the surface and an abrupt gradient within the channel region.

In an NMOS transistor which was fabricated to have the maximum channel impurity concentration identical to that of the MOSFET according to the second embodiment by doping only In by ion implantation, the NMOS transistor exhibited a significant source-drain leakage current due to a fault presumably caused by crystal defects, thus failing to provide good transistor characteristics.

<Third Embodiment>

FIG. 11 is a cross-sectional view illustrating a completed MOSFET according to a third embodiment of the present invention. After fabricating the MOSFET up to the state illustrated in FIG. 8 based on the second embodiment, P ions were further implanted into the N-conductive type high concentration well layer 22, while B ions were further implanted into the P-conductive type high concentration well layer 21, using the gate electrode 4 as an implantation blocking mask, under the conditions of an acceleration energy at 20 keV and a dose of 1×10¹³/cm², and acceleration energy of 20 keV and a dose of 6×10¹³/cm², respectively, to additionally form an N-conductive type pocket region 51 and a P-conductive type pocket region 5. Subsequently, the CMOS transistor was manufactured in accordance with the aforementioned second embodiment.

It was confirmed that a miniaturized CMOS transistor fabricated according to the third embodiment having a gate length of 60 nm, shorter than that of the CMOS transistor according to the second embodiment, normally operated without the surface punch-through phenomenon. However, no further improvement was provided on the maximum current value due to a higher concentration in the channel caused by the introduction of the pocket regions.

<Fourth Embodiment>

FIG. 12 is a cross-sectional view illustrating a completed MOSFET according to a fourth embodiment of the present invention. In the third embodiment, the N-conductive type pocket region 51 and P-conductive type pocket region 5 were additionally formed selectively in the source diffusion layer. In the fourth embodiment, the drain diffusion layer was selectively covered with a photo-resist film such that no ions were implanted thereinto. After the ion implantation, the resist film used for blocking the implantation was selectively removed. Subsequently, the CMOS transistor was manufactured in accordance with the aforementioned third embodiment.

It was confirmed that a miniaturized CMOS transistor fabricated according to the fourth embodiment normally operated even with a shorter gate length of 60 nm, identical to the third embodiment, without the surface punch-through phenomenon, and the maximum current value was improved over the CMOS transistor according to the third embodiment by slightly less than 5%. Presumably, the increase in current was accomplished due to difficulties in a reduction in a pinch off voltage caused by a higher concentration of the impurities in the substrate near the drain because of the absence of the pocket region formed in the drain diffusion layer. While the CMOS transistor according to the fourth embodiment has the source and drain in an asymmetric structure, no problem will arise in a circuit such as an inverter circuit in which a current flows in one direction at all times.

<Fifth Embodiment>

In the step of forming the In implanted layer 2 in the first embodiment, In was implanted at acceleration energy of 20 keV such that the maximum impurity concentration reached approximately 1×10¹⁸/cm³, and subsequently, Ga was doped by ion implantation at acceleration energy of 15 keV such that the maximum impurity concentration reached 2×10¹⁸/cm³. The maximum impurity concentration of Ga under the foregoing condition is provided at a depth of approximately 20 nm from the main surface, which matches with the depth at which the maximum impurity concentration of In is reached. Also, the foregoing depth substantially matches with a junction depth of the shallow source diffusion layer 7 and shallow drain diffusion layer 8. Since In exhibits a low solid solubility limit within Si, and additional In implantation simply causes crystal defects, Ga which exhibits a higher solid solubility limit than In should be used together as a means for realizing a high concentration and abrupt P-type impurity distribution. After doping Ga by ion implantation, the fabricating process steps after the short-time, high-temperature anneal were performed in accordance with the aforementioned first embodiment to fabricate a MOSFET according to the fifth embodiment. While the fifth embodiment has been described for the use of Ga together with In, Ga alone may be doped by ion implantation without the ion implantation of In for convenience, because Ga also has a characteristic of pinning other impurities.

Using a separately provided sample which had been doped with Ga ions by ion implantation and undergone the subsequent short-time high-temperature anneal, a depth profile distribution of the carrier concentration was measured by a spreading resistance measurement. The result of the measurement revealed a low concentration of approximately 8×10¹⁶/cm³ on the surface, and an abrupt distribution in which the carrier concentration reached approximately 8×10¹⁸/cm³ at a depth of 20 nm from the surface. A measurement of the MOSFET according to the fifth embodiment showed that a device having a gate length of 70 nm also had a large current characteristic, and were free from a leakage current due to a short channel effect or punch-through phenomenon. The foregoing characteristic suggests that the MOSFET according to the fifth embodiment is more appropriate for miniaturization than the MOSFET according to the first embodiment.

According to the foregoing embodiments, it is possible to realize a substrate impurity distribution in a channel region beneath a gate electrode with a low surface concentration both in the NMOS and PMOS transistors and an extremely abrupt impurity concentration gradient toward the inside of the semiconductor substrate, while still using B and P having a high activation rate. Therefore, a large current characteristic can be accomplished in a miniaturized CMOS transistor with a high mobility while sufficiently suppressing the surface punch-through phenomenon. Particularly, according to the present invention, the improvement on the impurity distribution can be made at a low cost only by adding a single process step of ion implantation. Also, according to the present invention, since the introduction of a high concentration substrate impurity region can be avoided near a drain junction in a semiconductor surface region which overlaps a gate electrode, no N⁺P⁺ high concentration tunnel junction is formed, thereby making it possible to reduce a leakage current in a standby state due to a GIDL phenomenon and accordingly reduce the power consumption.

It should be further understood by those skilled in the art that although the foregoing description has been made on embodiments of the invention, the invention is not limited thereto and various changes and modifications may be made without departing from the spirit of the invention and the scope of the appended claims.

What is claimed is:

1. A method of fabricating an insulated gate field effect transistor, comprising the steps of:
implanting a first impurity from a main surface of a semiconductor substrate having a first conductive type such that said first impurity reaches a maximum impurity concentration within said semiconductor substrate; and
implanting a second impurity having the first conductive type such that a depth at which said second impurity reaches a maximum impurity concentration substantially matches with a depth at which said first impurity reaches the maximum impurity concentration.

2. A method according to claim 1, wherein said step of implanting a first impurity and said step of implanting a second impurity are reversed in order.

3. A method according to claim 1, wherein said step of implanting a first impurity includes implanting said first impurity at an angle to the main surface of said semiconductor substrate except for the perpendicular.

4. A method of fabricating an insulated gate field effect transistor, comprising the steps of:
forming a first conductive type region and a second conductive type region on a main surface of the same semiconductor substrate;
implanting a first impurity from the main surface of said semiconductor substrate such that said first impurity reaches a maximum impurity concentration within said semiconductor substrate;
selectively implanting a second impurity having the first conductive type into said first conductive type region such that a depth at which said second impurity reaches a maximum impurity concentration substantially matches with a depth at which said first impurity reaches the maximum impurity concentration; and
selectively implanting a third impurity having a second conductive type into said second conductive type region such that a depth at which said third impurity reaches a maximum impurity concentration matches with the depth at which said first impurity reaches the maximum impurity concentration.

5. A method according to claim 4, wherein said step of implanting a first impurity is performed after said step of implanting a second impurity and said step of implanting a third impurity.

6. A method of manufacturing an insulated gate field effect transistor according to claim 1, wherein said first impurity is an impurity having a pinning effect on other impurities.

7. A method according to claim 6, wherein said first impurity is indium (In).

8. A method according to claim 5, wherein said first impurity includes at least one of indium (In) and gallium (Ga).

9. A method according to claim 1, wherein:
said step of implanting a second impurity having the first conductive type includes implanting said second impurity using a gate electrode as an implantation blocking mask,
wherein said method further comprising the step of:
forming a shallow source diffusion region having the second conductive type within a region in which said second impurity is implanted in said step of implanting, using the gate electrode as an implantation blocking mask.

10. A method according to claim 9, wherein said step of implanting the second impurity having the first conductive type using a gate electrode as an implantation blocking mask is performed after said step of forming a shallow source diffusion layer having the second conductive type using the gate electrode as an implantation blocking mask.

11. A method according to claim 4, further comprising the steps of:
implanting the second impurity having the first conductive type using a gate electrode formed through a gate insulating film on a main surface of said first conductive type region as an implantation blocking mask;
forming a shallow source diffusion layer having the second conductive type within a region in which said second impurity is implanted in said step of implanting the second impurity, using the gate electrode as an implantation blocking mask;
implanting the third impurity having the second conductive type using a gate electrode formed through the gate insulating film on a main surface of said second conductive type region as an implantation blocking mask; and
forming a shallow source diffusion layer having the first conductive type within a region in which said third impurity is implanted in said step of implanting the third impurity, using the gate electrode as an implantation blocking mask.

12. A method according to claim 11, wherein said step of implanting the second impurity having the first conductive type and said step of forming a shallow source diffusion layer having the second conductive type using the gate electrode as an implantation blocking mask, and said step of implanting the third impurity having the second conductive type and said step of forming a shallow source diffusion layer having the first conductive type using the gate electrode as an implantation blocking mask are performed in a reverse order.

13. An insulated gate field effect transistor comprising:
a gate electrode formed on a main surface of a semiconductor substrate having a first conductive type through an insulating film;
a first impurity region formed in a region of said semiconductor substrate beneath said gate electrode; and
a second impurity region having the first conductive type formed in a region of said semiconductor substrate beneath said gate electrode,
wherein said first impurity region and said second impurity region distribute such that said first and second impurity regions have their maximum impurity concentrations at the same depth within said semiconductor substrate, and the maximum impurity concentration in said second impurity region is higher than the maximum impurity concentration in said first impurity region.

14. An insulated gate field effect transistor comprising:
a first conductive type region, and a second conductive type region having a first conductive type in a main surface region of the same semiconductor substrate;
a gate electrode formed on a main surface of each of said first and second conductive type regions through an insulating film; and
a third impurity region having a second conductive type,
wherein said first and second impurity regions distribute in said first conductive type region of said semiconductor substrate beneath said gate electrode such that said first and second impurity regions have their maximum impurity concentrations at the same depth in said semiconductor substrate;
said first and third impurity regions distribute in said second conductive type region of said semiconductor substrate beneath said gate electrode such that said first and third impurity regions distribute such that said first and third impurity regions have their maximum impurity concentrations at the same depth in said semiconductor substrate; and
the maximum impurity concentration in each of said second and third impurity regions is higher than the maximum impurity concentration in said first impurity region.

15. An insulated gate field effect transistor according to claim 13, wherein:
said first impurity is an impurity having an effect of pinning said second and third impurities; and
each of said second and third impurities comprises one of boron (B), phosphor (P) and arsenic (As).

16. An insulated gate field effect transistor according to claim 13, further comprising:
source diffusion layers having a relatively shallow junction depth and deep junction depth, respectively,
wherein the depth at which the maximum impurity concentration is reached in said first impurity region is at the same depth as said shallow junction depth of said source diffusion layer, or above said shallow junction depth of said source diffusion layer.

17. An insulated gate field effect transistor according to claim 13, wherein said first impurity comprises indium (In).

18. An insulated gate field effect transistor according to claim 13, wherein said first impurity comprises indium (In) or gallium (Ga).

19. An insulated gate field effect transistor according to claim 13, wherein:
each of said second and third impurity regions exhibits an impurity concentration profile which has a gradient that is more abrupt from the maximum impurity concentration point to the main surface of said semiconductor substrate than from the maximum impurity concentration point to the inside of said semiconductor substrate.

20. An insulated gate field effect transistor according to claim 13, wherein the maximum impurity concentration in each of said second and third impurity regions is 1×10¹⁸/cm³ or higher.

21. An insulated gate field effect transistor according to claim 13, further comprising:
source diffusion layers including a shallow junction and a deep junction, respectively, wherein said second impurity region covers at least a bottom surface of said shallow junction.

22. An insulated gate field effect transistor according to claim 14, further comprising:
source diffusion layers respectively including a shallow junction and a deep junction in said first and second conductive type regions, respectively,
wherein said second impurity region or said third impurity region covers at least a bottom surface of the shallow junction of corresponding one of said source diffusion layers.
